(19) United States
(12) Patent Application Publication
(10) Pub. No.: US 2015/0173186 A1
(43) Pub. Date: Jun. 18, 2015

(54) STRETCHABLE DEVICE AND MANUFACTURING METHOD THEREOF

(71) Applicant: Electronics and Telecommunications Research Institute, Daejeon (KR)

(72) Inventors: Bock Soon NA, Daejeon (KR); Soon-Won JUNG, Daejeon (KR); Jae Bon KOO, Daejeon (KR); Chan Woo PARK, Daejeon (KR); Sang Chul LIM, Daejeon (KR); Sang Seok LEE, Sejong (KR); Kyoung Ik CHO, Daejeon (KR); Hye Yong CHU, Daejeon (KR)

(73) Assignee: Electronics and Telecommunications Research Institute, Daejeon (KR)

(21) Appl. No.: 14/280,205

(22) Filed: May 16, 2014

(30) Foreign Application Priority Data
Dec. 12, 2013 (KR) 10-2013-0154752

(51) Int. Cl. H05K 1/03; H05K 3/10; H05K 3/36; H05K 3/02

(52) U.S. Cl. CPC H05K 1/0306; H05K 3/02; H05K 3/103; H05K 3/361; H05K 3/366

(57) ABSTRACT

Provided is a stretchable devices. The stretchable device includes a first stretchable substrate having a first wavy surface that wrinkles in a first direction; first wiring lines extending along the first wavy surface in the first direction; a second stretchable substrate having a second wavy surface that faces the first wavy surface and wrinkles in a second direction intersecting the first direction, wherein the second stretchable substrate is disposed on the first stretchable substrate; second wiring lines extending along the second wavy surface in the second direction; and interlayer insulating layers disposed on the intersections of the first wiring lines and the second wiring lines and disposed between the first wiring lines and the second wiring lines.

### CROSS-REFERENCE TO RELATED APPLICATIONS

This U.S. non-provisional patent application claims priority under 35 U.S.C. §119 of Korean Patent Application No. 10-2013-0154752, filed on Dec. 12, 2013, the entire contents of which are hereby incorporated by reference.

### BACKGROUND OF THE INVENTION

The present invention disclosed herein relates to an electronic device and a manufacturing method thereof, and more particularly, to a stretchable device and a manufacturing method thereof.

Recently, research and development in a stretchable device that may maintain an electric function even though a substrate is expanded by external stress are actively performed.

A stretchable electronic circuit has applicability to various fields, such as sensor skin for a robot, a wearable communication device, a bio-device built in or attached to a human body, and a next-generation display beyond the limit of a typical flexible device that is simply bendable.

A shape of an electronic device may be deformed by using a stretchable substrate that may be bent or folded at will. A general stretchable device may include a wiring line which has a structure having high stretch. For example, the wiring line may be formed by the contraction of the stretchable substrate after being transferred to the surface of an inflated stretchable substrate. The wiring line may buckle into the surface of the stretchable substrate.

However, the expandability of a general stretchable device is limited by the amount of strain applied initially to a substrate, and it may be difficult to fold or extent the general stretchable device to have a desired form and in a desired direction. Also, the reliability in operation of general stretchable device may decrease because electronic device regions in addition to the wiring line also experience deformation as the deformation of a substrate increases.

Also, since a typical stretchable device has wiring lines extending in one direction, there may be a limitation in that it is vulnerable to strain provided in two directions.

### SUMMARY OF THE INVENTION

The present invention provides a stretchable device stretchable in two directions, and a manufacturing method thereof.

The present invention also provides a stretchable device that may enhance reliability in operation, and a manufacturing method thereof.

Embodiments of the inventive concept provide stretchable devices including a first stretchable substrate having a first wavy surface that wrinkles in a first direction; first wiring lines extending along the first wavy surface in the first direction; a second stretchable substrate having a second wavy surface that faces the first wavy surface and wrinkles in a second direction intersecting the first direction, wherein the second stretchable substrate is disposed on the first stretchable substrate; second wiring lines extending along the second wavy surface in the second direction; and interlayer insulating layers disposed on the intersections of the first wiring lines and the second wiring lines and disposed between the first wiring lines and the second wiring lines.

In some embodiments, the first stretchable substrate may include a first wrinkled region on which the first wavy surface is formed, and first device regions corresponding to the intersections.

In other embodiments, the stretchable device may further include electronic devices disposed between the interlayer insulating layer on the first device regions and the first wiring lines.

In still other embodiments, the electronic devices may include semiconductor devices or a light source device.

In even other embodiments, the stretchable device of claim 3 may further include lower insulating layers formed between the first wiring lines and the first stretchable substrate of the first device regions.

In yet other embodiments, the lower insulating layers may have a vessel shape that surrounds the electronic devices and the interlayer insulating layer.

In further embodiments, the lower insulating layers may include a silicon oxide layer or a silicon nitride layer.

In still further embodiments, the second stretchable substrate may include a second wrinkled region on which the second wavy surface is formed, and second device regions corresponding to the intersections.

In even further embodiments, the second device regions may include an interconnection planarization surface.

In yet further embodiments, the first device regions and the second device regions may have the same shape.

In much further embodiments, the stretchable device may further include third wiring lines that are parallel to the second wiring lines and extending along the second wavy surface in the second direction.

In still much further embodiments, the stretchable device may further include fourth wiring lines that are parallel to the first wiring lines and extending along the first wavy surface in the first direction.

In even much further embodiments, each of the first stretchable substrate and the second stretchable device may include polydimethylsiloxane (PDMS).

In other embodiments of the inventive concept, methods of manufacturing a stretchable device include forming a first wavy surface wrinkling in a first direction on a first wrinkled region of a first stretchable substrate, first wiring lines extending along the first wavy surface in the first direction, and interlayer insulating layers on some of the first wiring lines; forming a second wavy surface wrinkling in a second direction intersecting the first direction on a lower surface of a second substrate facing the first stretchable substrate, and second wiring lines extending along the second wavy surface in the second direction; and bonding the first stretchable substrate to the second stretchable substrate [symbol] enable the first wiring lines and the second wiring lines to intersect on and under the interlayer insulating layer.

In some embodiments, the forming of the first wavy surface, the first wiring lines and the interlayer insulating layers may include: providing a first mold substrate that has a first wavy mold surface wrinkling in a first direction and first planar mold surfaces formed on the first wavy mold surface in the shape of islands; forming the interlayer insulating layers on the first planar mold surfaces; forming the first wiring lines extending in the first direction on the interlayer insulating layers and the first wavy mold surface; forming the first stretchable substrate on the first wiring lines, the interlayer insulating layers and the first wavy mold surface; and removing the first mold substrate.

In other embodiments, the method may further include: forming a first sacrificial layer between the first planar mold surfaces and the interlayer insulating layers; and removing the first sacrificial layer when removing the first mold substrate.

In still other embodiments, the method may further include forming electronic devices between the first wiring lines and the interlayer insulating layers.

In even other embodiments, the method may further include forming a lower insulating layer between the first wiring lines and the first stretchable substrate.

In yet other embodiments, the forming of the second wavy surface and the second wiring lines may include: providing a second mold substrate that has a second wavy mold surface wrinkling in a second direction, and second planar mold surfaces formed on the second wavy mold surface in the shape of islands; forming second wiring lines extending in the second direction on the second wavy mold surface and the second planar mold surfaces; forming the second stretchable substrate on the second wiring lines and the second mold substrate; and removing the second mold substrate.

In further embodiments, the method may further include: forming a second sacrificial on the second wavy mold surface and the second planar mold surfaces after providing the second mold substrate; and removing the second sacrificial layer when removing the second mold substrate.

### BRIEF DESCRIPTION OF THE DRAWINGS

The accompanying drawings are included to provide a further understanding of the present invention, and are incorporated in and constitute a part of this specification. The drawings illustrate exemplary embodiments of the inventive concept and, together with the description, serve to explain principles of the present invention. In the drawings:

FIG. 1 is a circuit diagram for explaining a stretchable device according to an embodiment of the inventive concept;

FIG. 2 is a plane view of FIG. 1;

FIG. 3 is a cross-sectional view taken along a data line of FIG. 2;

FIG. 4 is a cross-sectional view taken along a gate line of FIG. 2;

FIG. 5 is a plane view of a stretchable device according to an application of the present invention;

FIG. 6 is a cross-sectional view taken along power supply lines of FIG. 5;

FIGS. 7 to 19 are process, cross-sectional views of a method of manufacturing a stretchable device according to an embodiment of the inventive concept based on FIG. 3.

FIG. 20 is a plane view of a lower stretchable substrate of FIG. 14; and

FIG. 21 is a plane view of an upper stretchable substrate of FIG. 19.

### DETAILED DESCRIPTION OF PREFERRED EMBODIMENTS

Exemplary embodiments of the inventive concept are described below in more detail with reference to the accompanying drawings. The effects and features of the present invention, and implementation methods thereof will be clarified through following embodiments described with reference to the accompanying drawings. However, the present invention is not limited embodiments to be described below but may be implemented in other forms. Rather, these embodiments are provided so that this disclosure will be thorough and complete, and will fully convey the scope of the present invention to those skilled in the art, and furthermore, the present invention is only defined by scopes of claims. The same reference numerals throughout the disclosure refer to the same components.

The terms used herein are only for explaining embodiments while not limiting the present invention. The terms of a singular form may include plural forms unless referred to the contrary. The terms used herein “includes”, “comprises”, “including” and/or “comprising” do not exclude the presence or addition of one or more components, steps, operations and/or elements other than the components, steps, operations and/or elements that are mentioned. Furthermore, since the following description presents an exemplary embodiment, the reference numerals presented according to the order of the description is not limited thereto.

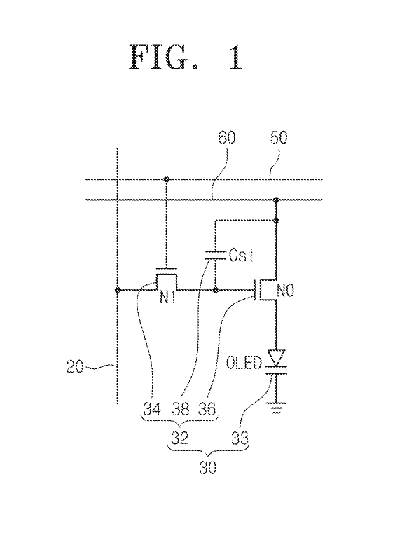

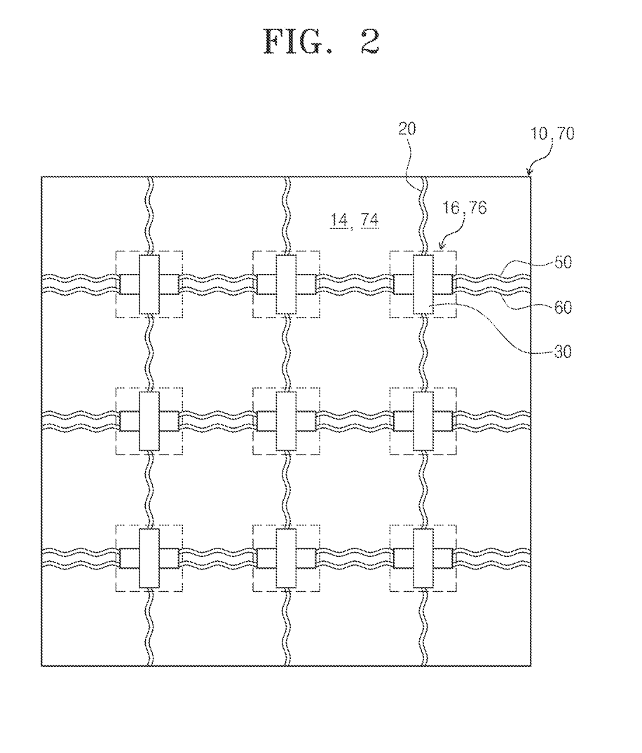

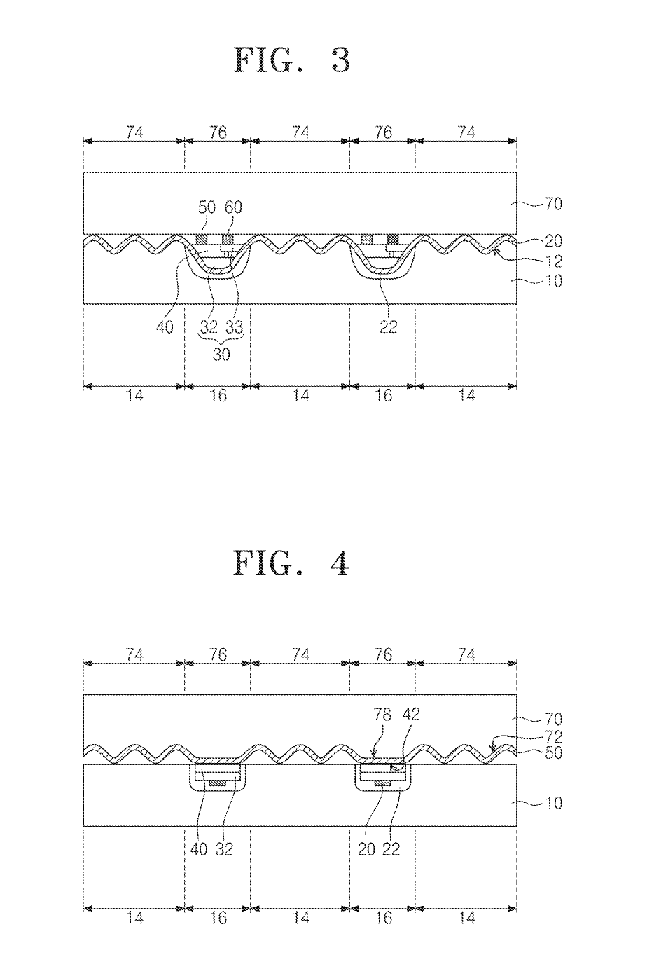

FIG. 1 is a circuit diagram for explaining a stretchable device according to an embodiment of the inventive concept. FIG. 2 is a plane view of FIG. 1. FIG. 3 is a cross-sectional view taken along data lines 20 of FIG. 2. FIG. 4 is a cross-sectional view taken along a gate line 50 of FIG. 2.

Referring to FIGS. 1 to 4, the stretchable device according to an embodiment of the inventive concept may include a lower stretchable substrate 10, data lines 20, electronic devices 30, an interlayer insulating layer 40, gate lines 50, power supply lines 60, and an upper stretchable substrate 70.

The lower stretchable substrate 10 may include first wrinkled regions 14 and first device regions 16. The first wrinkled region 14 is a region where a first wavy surface 12 is formed on the upper surface of the lower stretchable substrate 10. The first wavy surface 12 may wrinkle in a first direction. The first device regions 16 are regions where electronic devices 30 are formed. The first device regions 16 may be disposed in the first wrinkled regions 14 in the shape of islands. For example, the first device regions 16 may be rectangles. However, the present embodiment is not limited thereto. The first device regions 16 may be various shapes such as circles, triangles, or pentagons. The lower stretchable substrate 10 may include polydimethylsiloxane (PDMS).

The data lines 20 may be disposed on the first wavy surface 12. The data lines 20 may be extending in a first direction. The data lines 20 may be bent upwardly and downwardly along the first wavy surface 12.

The data lines 20 may contract or inflate in a first direction along the lower stretchable substrate 10. For example, the data lines 20 may include a metal such as platinum (Au), silver (Ag), copper (Cu), aluminum (Al), tungsten (W), molybdenum (Mo), nickel (Ni), or cobalt (Co).

The electronic devices 30 may be disposed on the first device regions 16. The electronic devices 30 may be disposed on the intersections of the data lines 20 and the gate lines 50. The electronic devices 30 may include a semiconductor device 32 and a light source device 33. The semiconductor device 32 may include an addressing transistor 34, a power transistor 36, and a capacitor 38. The light source device 33 may include an organic light-emitting device.

The lower insulating layers 22 may be disposed between the electronic devices 30 and the lower stretchable substrate 10. The lower insulating layers 22 may have a vessel shape that surrounds the data lines 20 of the first device regions 16 and the electronic devices 30. The lower insulating layers 22 may include a silicon oxide layer or a silicon nitride layer.

The interlayer insulating layer 40 may be disposed on the electronic devices 30. The electronic devices 30 may be insulated from the gate lines 50 by the interlayer insulating layer 40. The interlayer insulating layer 40 may provide a device planarization surface 42 of the loser stretchable substrate 10. The interlayer insulating layer 40 and the lower insulating layers 22 may surround some of the data lines 20 and the electronic devices 30. The present invention is not limited thereto and various variations may be implemented. For example, the gate lines 50 and the power supply lines 60 may also be electrically connected to the electronic devices 30 through the contact hole (not shown) of the interlayer insulating layer 40.

The upper stretchable substrate 70 may be disposed on the lower stretchable substrate 10. The upper stretchable substrate 70 may include second wrinkled regions 74 and second device regions 76. The second wrinkled region 74 is a region where a second wavy surface 72 is formed on the lower surface of the upper stretchable substrate 70. The second wavy surface 72 may wrinkle in a second direction. The first direction and the second direction may intersect. The second device regions 76 are regions where the gate lines 50 are in contact with the interlayer insulating layer 40. The second device regions 76 may be disposed in the second wrinkled regions 74 in the shape of islands. The second device regions 76 may have interconnection planarization surfaces 78. The first device regions 16 may be aligned with the second device regions 76. According to an example, the first device regions 16 and the second device regions 76 may have the same shape. For example, the second device regions 76 may be rectangles. The present embodiment is not limited thereto. The second device regions 76 may be various shapes such as circles, triangles, or pentagons. The upper stretchable substrate 70 and the lower stretchable substrate 10 may contract or inflate in two directions by an external force.

The gate lines 50 may be disposed under the second wavy surface 72 and the interconnection planarization surface 78. The gate lines 50 may be extending in a second direction. The gate lines 50 may be bent upwardly and downwardly along the second wavy surface 72. The gate lines 50 may contract or inflate in the second direction along the upper stretchable substrate 70. The gate lines 50 may be connected to the electronic devices 30. When the upper stretchable substrate 70 contacts or inflates in the first direction, damage to the gate lines 50 may be minimized. Likewise, when the lower stretchable substrate 10 contacts or inflates in the second direction, damage to the data lines 50 may be minimized.

The first device regions 16 and the second device regions 76 may correspond to the intersections of the first device regions 16 and the second device regions 76. The gate lines 50 and the data lines 20 may define sub pixels.

The power supply lines 50 may be parallel to the gate lines 50. The power supply lines 60 may be extending in a second direction. The power supply lines 60 may be disposed under the second wavy surface 72 and the interconnection planarization surface 78 although not shown. The power supply lines 60 may be bent upwardly and downwardly along the second wavy surface 72. The power supply lines 60 may be connected to the electronic devices 30 under the interconnection planarization surface 78. The power supply lines 60 may contract or inflate in the second direction along the upper stretchable substrate 70.

The lower stretchable substrate 10 and the upper stretchable substrate 70 may contract or inflate in two directions by an external force. Likewise, the data lines 20 and the gate lines 50 may contract or inflate in two directions. The data lines 20 and the gate lines 50 may not be disconnected.

Thus, the stretchable device according to an embodiment of the inventive concept may enhance reliability in operation.

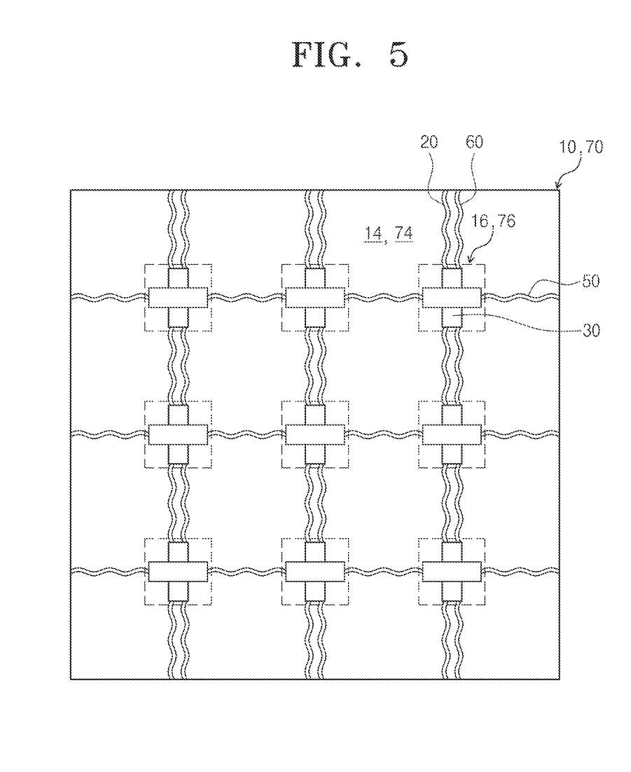

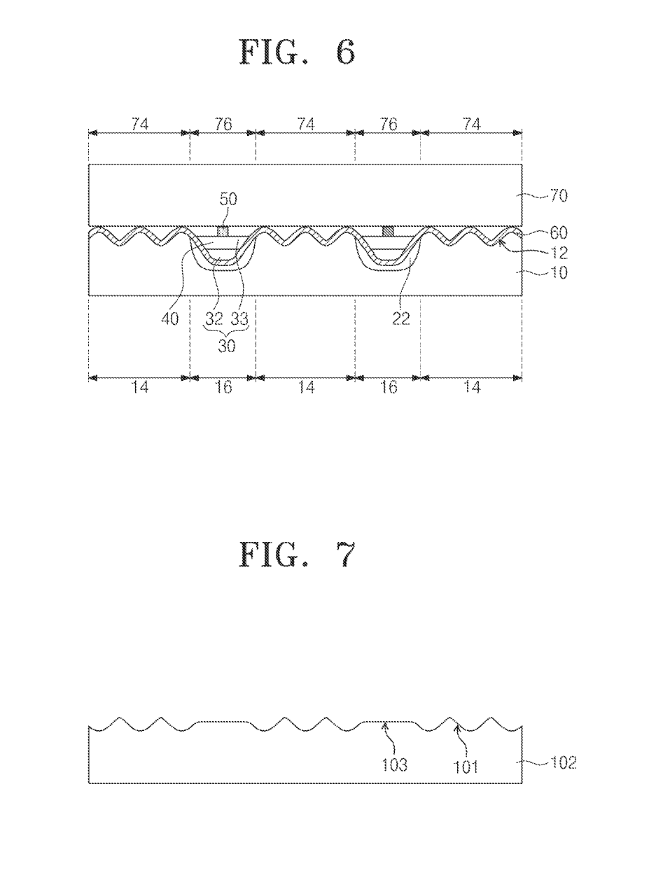

FIG. 5 is a plane view of a stretchable device according to an application of the present invention. FIG. 6 is a cross-sectional view taken along data lines 60 of FIG. 5.

Referring to FIGS. 5 and 6, the stretchable device according to an application of the present invention may include power supply lines 60 parallel to the data lines 20. The power supply lines 60 may be extending in a first direction. The data lines 60 may be disposed on the first wavy surface 12. The power supply lines 60 may be bent upwardly and downwardly along the second wavy surface 12. The power supply lines 60 in the first device regions 16 may be disposed between the lower insulating layers and the electronic devices 30. The application shows that the power supply lines 60 of the embodiment are parallel to the data lines 20.

A method of manufacturing the stretchable device according to the embodiment of the inventive concept having such a configuration is as follows.

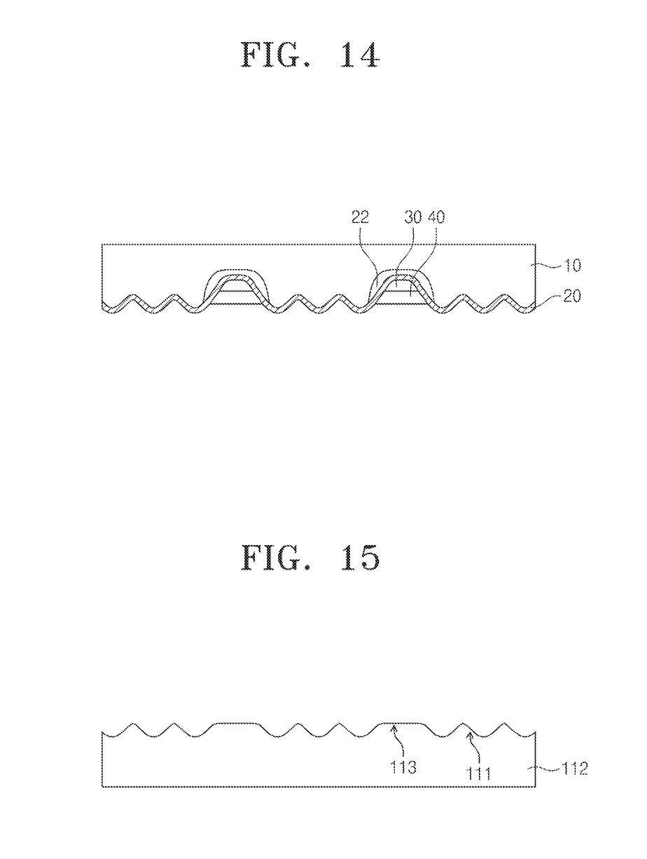

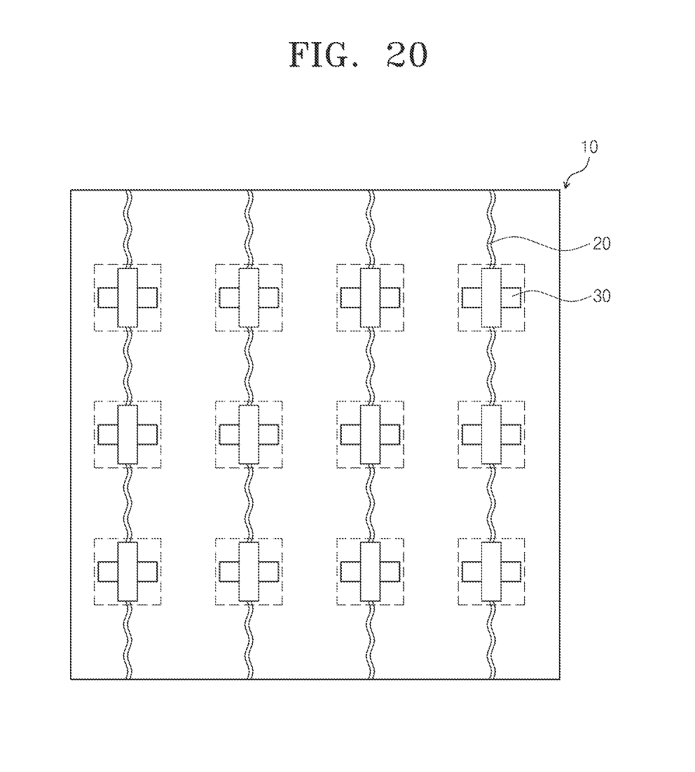

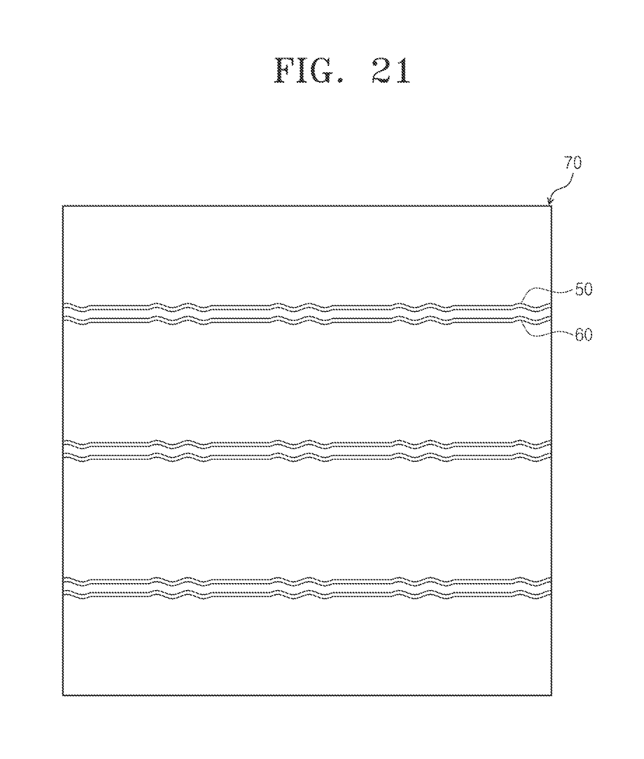

FIGS. 7 to 19 are process, cross-sectional views of a method of manufacturing a stretchable device according to an embodiment of the inventive concept based on FIG. 3. FIG. 20 is a plane view of the lower stretchable substrate 10 of FIG. 14. FIG. 21 is a plane view of the upper stretchable substrate of FIG. 19.

Referring to FIG. 7, a first mold substrate 102 is provided. The first mold substrate 102 may include a silicon wafer. The first mold substrate 102 may have first wavy mold surfaces 101 and first planar mold surfaces 103. The first wavy surface 101 may wrinkle in a first direction. The first planar mold surfaces 103 may be formed in the first wavy mold surfaces 101 in the shape of islands. The first wavy mold surfaces 101 and the first planar mold surfaces 103 may be formed by a photolithography process and an etching process. The etching process may be performed by wet etching.

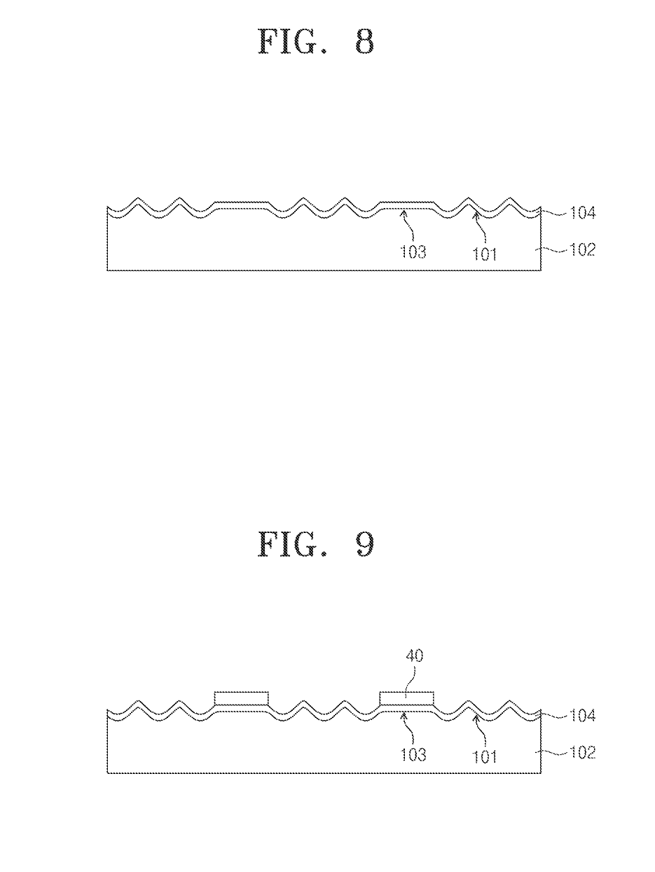

Referring to FIG. 8, a sacrificial layer 104 is formed on the first mold substrate 102. The first sacrificial layer 104 may include a dielectric layer such as a silicon oxide layer or a silicon nitride layer. The dielectric layer may be formed by chemical vapor deposition (CVD) Also, the first sacrificial layer 104 may include an organic material such as resist or a polymer.

The organic material may be formed by spin coating or by a sol-gel process.

Referring to FIG. 9, the interlayer insulating layer 40 is formed on the first planar mold surface 103. The interlayer insulating layer 40 may include a silicon oxide layer or a silicon nitride layer. When the interlayer insulating layer 40 and the first sacrificial layer 104 are formed of a silicon oxide layer, the first sacrificial layer 104 may include a TEOS silicon oxide layer having low density and the interlayer insulating layer 40 may include a HDCVD silicon layer having relatively high density.

Referring to FIG. 10, the electronic devices 30 are formed on the interlayer insulating layer 40. The electronic devices 30 may be bonded onto the interlayer insulating layer 40. Also, the electronic devices 30 may be formed by unit processes. The unit processes may include a semiconductor layer deposition process, a photolithography process and an etching process.

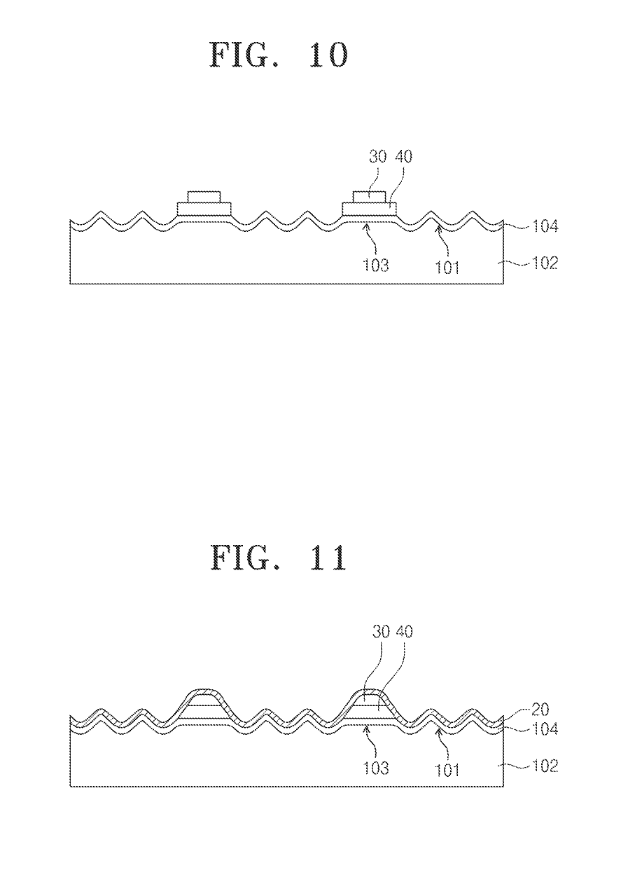

Referring to FIG. 11, the data lines 20 are provided on the electronic devices 30 and the first mold substrate 102. The data lines 20 may be connected to the electronic devices 30. The data lines 20 may be extending in a first direction. The data lines 20 may be formed to be bent upwardly and downwardly along the first wavy surface 101.

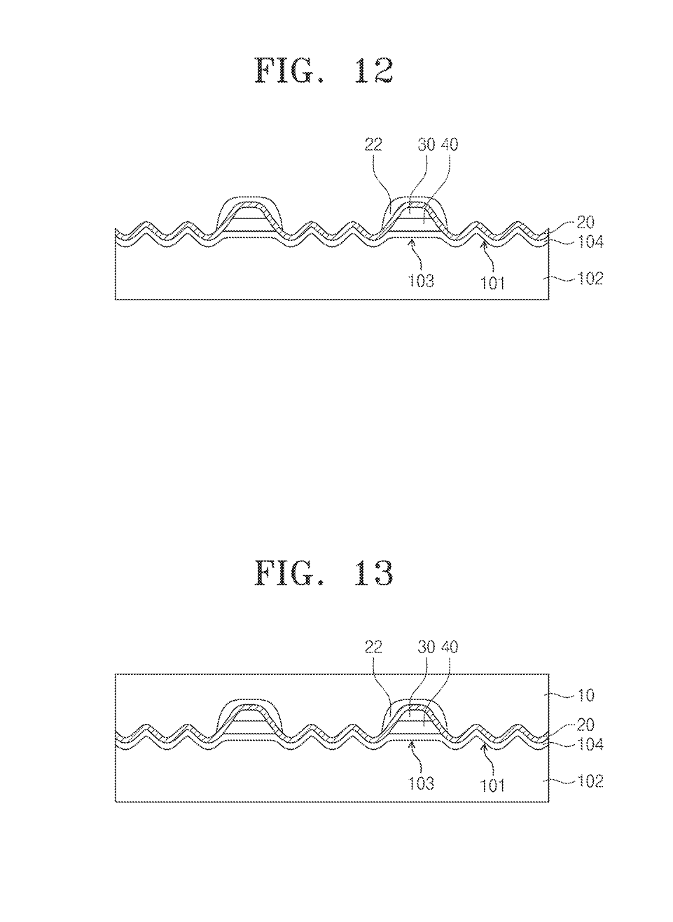

Referring to FIG. 12, the lower insulating layers 22 are formed which surround some of the data lines 20 and the electronic devices 30. The lower insulating layers 22 may include a silicon oxide layer or a silicon nitride layer. The lower insulating layers may be formed by CVD, the photolithography process and the etching process.

Referring to FIG. 13, the lower stretchable substrate 10 is formed as a whole on the first mold substrate 102. The lower stretchable substrate 10 may include PDMS. The lower stretchable substrate 10 may be formed by spin coating or printing.

Referring to FIGS. 14 and 20, the first mold substrate 102 and the first sacrificial layer 104 are removed. The first mold substrate 102 and the first sacrificial layer 104 may be removed by the etching process. The etching process may be performed by wet etching or dry etching. The data lines 20 may be extending on the lower stretchable substrate 10 in a first direction.

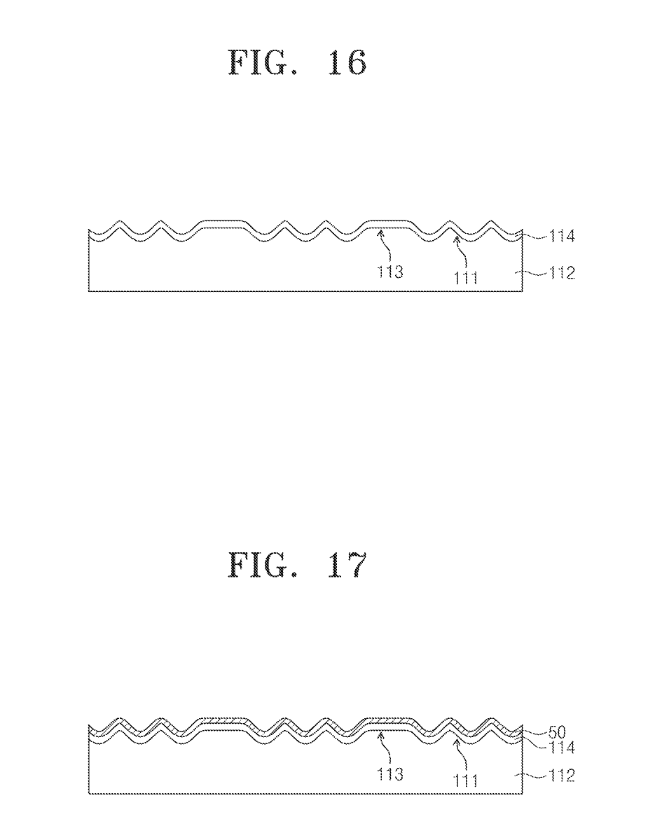

Referring to FIG. 15, a second mold substrate 112 is provided. The second mold substrate 112 may include a silicon wafer. The second mold substrate 112 may have second wavy mold surfaces 111 and second planar mold surfaces 113. The second wavy surface 111 may wrinkle in a second direction. The second planar mold surfaces 113 may be formed in the second wavy mold surfaces 111 in the shape of islands. The second wavy mold surfaces 111 and the second planar mold surfaces 113 may be formed by a photolithography process and an etching process.

Referring to FIG. 16, a second sacrificial layer 114 is formed on the second mold substrate 112. The second sacrificial layer 114 may include an inorganic layer such as a silicon oxide layer or a silicon nitride layer. The second sacrificial layer 114 may include an organic material such as resist or a polymer.

Referring to FIGS. 2 and 17, the gate lines 50 and the power supply lines 60 are formed on the second sacrificial layer 114. The gate lines 50 and the power supply lines 60 may be formed in a second direction along the second wavy mold surface 111 and the second planar mold surface 113. The gate lines 50 and the power supply lines 60 may be formed by a metal deposition process, a photolithography process, and an etching process. The power supply lines 60 may be disposed on the same layer as the gate lines 50 although not shown in FIG. 17.

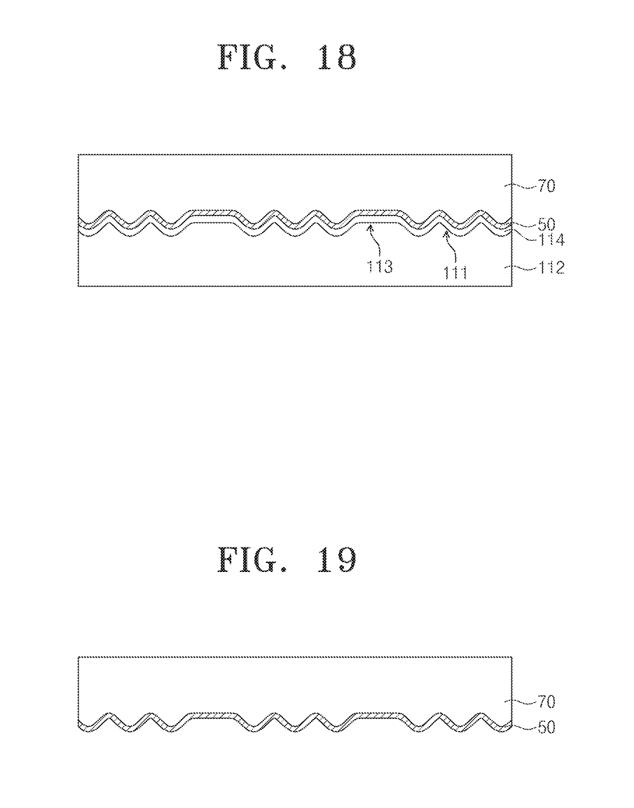

Referring to FIG. 18, the upper stretchable substrate 70 is formed as a whole on the second mold substrate 112. The upper stretchable substrate 70 may include PDMS. The upper stretchable substrate 70 may be formed by spin coating or printing.

Referring to FIGS. 19 and 21, the second mold substrate 112 and the second sacrificial layer 114 are removed. The second mold substrate 112 and the second sacrificial layer 114 may be removed by an etching process. The etching process may be performed by wet etching or dry etching. The gate lines 50 and the power supply lines 60 may be extending on the upper stretchable substrate 70 in a second direction.

Referring to FIGS. 1 and 3, the lower stretchable substrate 10 is bonded to the upper stretchable substrate 70. Bonding of the lower stretchable substrate 10 and the upper stretchable substrate 70 may be include a mechanical bonding process. The first device regions 16 may be aligned with the second device regions 76. The lower stretchable substrate 10 and the upper stretchable substrate 70 may be bonded by adhesive although not shown.

As described above, the stretchable device according to embodiments of the inventive concept may include the lower stretchable substrate, the data lines, the interlayer insulating layer, the gate lines, and the upper stretchable substrate. The lower stretchable substrate may have the first wavy surface in a first direction. The data line may be extending along the first wavy surface in the first direction. The upper stretchable substrate may have the second wavy surface in a second direction. The gate line may be extending along the second wavy surface in the second direction. The lower stretchable substrate and the upper stretchable substrate may be combined in a direction in which the data line and the gate line intersect. The data line and the gate line may be insulated by the interlayer insulating layer. The lower stretchable substrate and the upper stretchable substrate may be stretched in two directions by an external force. Likewise, the data line and the gate line may be stretched in two directions. The data line and the gate line may not be disconnected.

Thus, the stretchable device according to embodiments of the inventive concept may enhance reliability in operation.

While embodiments of the inventive concept are described with reference to the accompanying drawings, a person skilled in the art will be able to understand that the present invention may be practiced as other particular forms without changing essential characteristics. Therefore, embodiments described above should be understood as illustrative and not limitative in every aspect.

What is claimed is:

1. A stretchable device comprising:
a first stretchable substrate having a first wavy surface that wrinkles in a first direction;
first wiring lines extending along the first wavy surface in the first direction;
a second stretchable substrate having a second wavy surface that faces the first wavy surface and wrinkles in a second direction intersecting the first direction, wherein the second stretchable substrate is disposed on the first stretchable substrate;
second wiring lines extending along the second wavy surface in the second direction; and
interlayer insulating layers disposed on the intersections of the first wiring lines and the second wiring lines and disposed between the first wiring lines and the second wiring lines.

2. The stretchable device of claim 1, wherein the first stretchable substrate comprises a first wrinkled region on which the first wavy surface is formed, and first device regions corresponding to the intersections.

3. The stretchable device of claim 1, further comprising electronic devices disposed between the interlayer insulating layer on the first device regions and the first wiring lines.

4. The stretchable device of claim 3, wherein the electronic devices comprise semiconductor devices or a light source device.

5. The stretchable device of claim 3, further comprising lower insulating layers formed between the first wiring lines and the first stretchable substrate of the first device regions.

6. The stretchable device of claim 5, wherein the lower insulating layers have a vessel shape that surrounds the electronic devices and the interlayer insulating layer.

7. The stretchable device of claim 5, wherein the lower insulating layers comprise a silicon oxide layer or a silicon nitride layer.

8. The stretchable device of claim 2, wherein the second stretchable substrate comprises a second wrinkled region on which the second wavy surface is formed, and second device regions corresponding to the intersections.

9. The stretchable device of claim 8, wherein the second device regions comprise an interconnection planarization surface.

10. The stretchable device of claim 8, wherein the first device regions and the second device regions have the same shape.

11. The stretchable device of claim 1, further comprising third wiring lines that are parallel to the second wiring lines and extending along the second wavy surface in the second direction.

12. The stretchable device of claim 1, further comprising fourth wiring lines that are parallel to the first wiring lines and extending along the first wavy surface in the first direction.

13. The stretchable device of claim 1, wherein each of the first stretchable substrate and the second stretchable device comprises polydimethylsiloxane (PDMS).

14. A method of manufacturing a stretchable device, the method comprising:
forming a first wavy surface wrinkling in a first direction on a first wrinkled region of a first stretchable substrate, first wiring lines extending along the first wavy surface in the first direction, and interlayer insulating layers on some of the first wiring lines;
forming a second wavy surface wrinkling in a second direction intersecting the first direction on a lower surface of a second substrate facing the first stretchable substrate, and second wiring lines extending along the second wavy surface in the second direction; and
bonding the first stretchable substrate to the second stretchable substrate to enable the first wiring lines and the second wiring lines to intersect on and under the interlayer insulating layer.

15. The method of claim 14, wherein the forming of the first wavy surface, the first wiring lines and the interlayer insulating layers comprises:
providing a first mold substrate that has a first wavy mold surface wrinkling in a first direction and first planar mold surfaces formed on the first wavy mold surface in the shape of islands;
forming the interlayer insulating layers on the first planar mold surfaces;
forming the first wiring lines extending in the first direction on the interlayer insulating layers and the first wavy mold surface;
forming the first stretchable substrate on the first wiring lines, the interlayer insulating layers and the first wavy mold surface; and
removing the first mold substrate.

16. The method of claim 15, further comprising:
forming a first sacrificial layer between the first planar mold surfaces and the interlayer insulating layers; and
removing the first sacrificial layer when removing the first mold substrate.

17. The method of claim 15, further comprising forming electronic devices between the first wiring lines and the interlayer insulating layers.

18. The method of claim 15, further comprising forming a lower insulating layer between the first wiring lines and the first stretchable substrate.

19. The method of claim 14, wherein the forming of the second wavy surface and the second wiring lines comprises:
providing a second mold substrate that has a second wavy mold surface wrinkling in a second direction, and second planar mold surfaces formed on the second wavy mold surface in the shape of islands;
forming second wiring lines extending in the second direction on the second wavy mold surface and the second planar mold surfaces;
forming the second stretchable substrate on the second wiring lines and the second mold substrate; and
removing the second mold substrate.

20. The method of claim 19, further comprising:
forming a second sacrificial on the second wavy mold surface and the second planar mold surfaces after providing the second mold substrate; and
removing the second sacrificial layer when removing the second mold substrate.
